(19) United States
(12) Patent Application Publication
(10) Pub. No.: US 2008/0209718 A1
(43) Pub. Date: Sep. 4, 2008

(54) Method of manufacturing multi-layered printed circuit board

(75) Inventors: Chan yeup Chung, Daegu (KR); Geun Ho Kim, Daejeon (KR); Seong Woo Choi, Busan (KR); Dek Gin Yang, Chungcheongbuk-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/007,265

(22) Filed: Jan. 8, 2008

(30) Foreign Application Priority Data
Mar. 2, 2007 (KR) 10-2007-0021039

(51) Int. Cl. H05K 3/00; H05K 3/20

(52) U.S. Cl. 29/831; 29/829; 29/852

(57) ABSTRACT

The present invention relates to a method of manufacturing a multi-layered printed circuit board which can decrease the cost and time required to produce the printed circuit board and can improve heat radiation characteristics and bending strength.

### CROSS REFERENCE TO RELATED APPLICATION

This application claims the benefit of Korean Patent Application No. 10-2007-0021039, filed Mar. 2, 2007, entitled “Fabricating Method of Multi Layer Printed Circuit Board”, which is hereby incorporated by reference in its entirety into this application.

### BACKGROUND OF THE INVENTION

1. Field of the Invention

The present invention relates to a method of manufacturing a multi-layered printed circuit board, and, more particularly, to a method of manufacturing a multi-layered printed circuit board which can decrease the cost and time required to produce the printed circuit board and can improve heat radiation characteristics and bending strength.

2. Description of the Related Art

A printed circuit board (PCB) serves to electrically connect electronic parts thereto and mechanically fix them thereon, and includes an insulation layer which is formed of phenol resin, epoxy resin, or the like, and a copper foil layer which is adhered on the insulation layer and in which a predetermined wiring pattern is formed.

Such a printed circuit board includes a one-sided printed circuit board, in which a wiring pattern is formed on only one side of an insulation layer, a double-sided printed circuit board, in which wiring patterns are formed on both sides of an insulation layer, and a multi-layered printed circuit board, in which wiring patterns are provided in multiple layers.

The method of manufacturing such a multi-layered printed circuit board includes the steps of fabricating a core by impregnating a woven glass fiber with BT resin, FR-4 resin or the like, forming an inner-layer circuit by layering copper foil on both sides of the core, and fabricating the printed circuit board through a subtractive process or a semi-additive process.

FIGS. 1A to 1C are process views showing a conventional method of manufacturing a multi-layered printed circuit board.

The conventional process of manufacturing a multi-layered printed circuit board will be described below with reference to FIGS. 1A to 1C.

First, as shown in FIG. 1A, a copper clad laminate, in which copper foils are layered on both sides of a first insulation layer 2, is provided, and then a dry film (not shown) is applied on the copper foil.

Subsequently, an inner-layer circuit pattern 4 is formed through a photo exposure process and a development process.

After the inner-layer circuit pattern 4 is formed, as shown in FIG. 1B, second insulation layers 8 are layered on the inner-layer circuit pattern, and then a via hole is formed through a drilling process.

After the via hole 6 is formed, a copper plated layer is formed on the inner wall of the via hole 6 and the second insulation layers 8 through an electroless copper plating process and an electrolytic copper plating process, and then a dry film (not shown) is applied on the copper plated layer.

Subsequently, a first outer-layer circuit pattern 4a is formed through a photo exposure process and a development process.

After the first outer-layer circuit pattern 4a is formed, as shown in FIG. 1C, a third insulation layer 10 is layered on the first outer-layer circuit pattern 4a, and then blind via holes are formed using a laser drill such that the first outer-layer circuit pattern 4a is partially exposed.

Subsequently, a copper plated layer is formed on the inner wall of each of the blind via holes and the third insulation layer 10 through an electroless copper plating process and an electrolytic copper plating process, a dry film (not shown) is applied on the copper plated layer, and then a second outer-layer circuit pattern 4b is formed through a photo exposure process and a development process.

Here, electroconductive paste 12 is packed into each of the blind via holes in order to form a circuit layer having 8 or more layers. However, in the case where a circuit layer having 6 or less layers is formed, electroconductive paste 12 need not be packed into each of the blind via holes.

In this way, the conventional method of manufacturing a multi-layered printed circuit board is problematic in that, since drilling, plating and circuit forming processes are repeatedly performed depending on the number of repetitions of a layering process after an inner-layer circuit pattern 4 is formed on a copper clad laminate, the cost and time required to produce the multi-layered printed circuit board are increased.

That is, in the conventional method of manufacturing a multi-layered printed circuit board, since the multi-layered printed circuit board is manufactured using a sequential layering method of sequentially layering a plurality of circuit layers, the insulation layers 8 and 10 are heated and pressed using a vacuum press at the time of layering the plurality of circuit layers, and thus there is a problem in that the production cost and time for manufacturing the multi-layered printed circuit board are increased.

Further, since the conventional multi-layered printed circuit board does not include a heat radiation plate for radiating heat generated therein due to the high-integration and high-functionalization of active devices, there is a problem in that the reliability of the printed circuit board is decreased.

### SUMMARY OF THE INVENTION

Accordingly, the present invention has been made keeping in mind the above problems occurring in the prior art, and the present invention provides a method of manufacturing a multi-layered printed circuit board which can decrease the time and cost required to produce a printed circuit board and can improve heat radiation characteristics and bending strength.

In one aspect, the present invention provides a method of manufacturing a multi-layered printed circuit board, including (a) preparing a polyimide copper clad laminate (CCL), in which copper foils are layered on both sides of a polyimide layer, and then removing portions of the copper foils corresponding to via holes to be formed, to form windows through which the polyimide layer is exposed; (b) forming the via holes in the polyimide layer such that the copper foil formed beneath the polyimide layer is exposed through the windows; (c) forming a copper plating layer on an inner wall of the via holes and the copper foil and then forming a circuit pattern; and (d) sequentially disposing the first polyimide CCL in which the circuit pattern is formed, a first prepreg, an aluminum core layer, a second prepreg, and the second polyimide CCL, in which the circuit pattern is formed, forming bumps between the aluminum core layer and the circuit patterns, and then pressing them using a press while heating them.

In another aspect, the present invention provides method of manufacturing a multi-layered printed circuit board, including (a) preparing a polyimide copper clad laminate (CCL), in which copper foils are layered on both sides of a polyimide layer, and then removing portions of the copper foils corresponding to via holes to be formed, to form windows through which the polyimide layer is exposed; (b) forming the via holes in the polyimide layer such that the copper foil, formed beneath the polyimide layer, is exposed through the windows; (c) forming a copper plating layer on an inner wall of the via holes and the copper foil and then forming a first circuit pattern; (d) sequentially layering a prepreg and a copper foil on both sides of an aluminum core layer and then forming a second circuit pattern using the copper foil; and (e) sequentially disposing the first polyimide CCL in which the first circuit pattern is formed, the aluminum core layer in which the second circuit pattern is formed, and the second polyimide CCL in which the first circuit pattern is formed, forming bumps between the first circuit patterns and the second circuit patterns, and then pressing them using a press while heating them.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1C are process views showing a conventional method of manufacturing a multi-layered printed circuit board;

FIGS. 2A to 2E are process views showing a method of manufacturing a multi-layered printed circuit board according to a first embodiment of the present invention;

FIG. 3 is a cross-sectional view showing a multi-layered printed circuit board manufactured using the method shown in FIGS. 2A to 2E, according to a second embodiment of the present invention;

FIG. 4 is a cross-sectional view showing a multi-layered printed circuit board manufactured using the method shown in FIGS. 2A to 2E, according to a third embodiment of the present invention; and

FIG. 5 is a cross-sectional view showing a multi-layered printed circuit board manufactured using the method shown in FIGS. 2A to 2E, according to a fourth embodiment of the present invention.

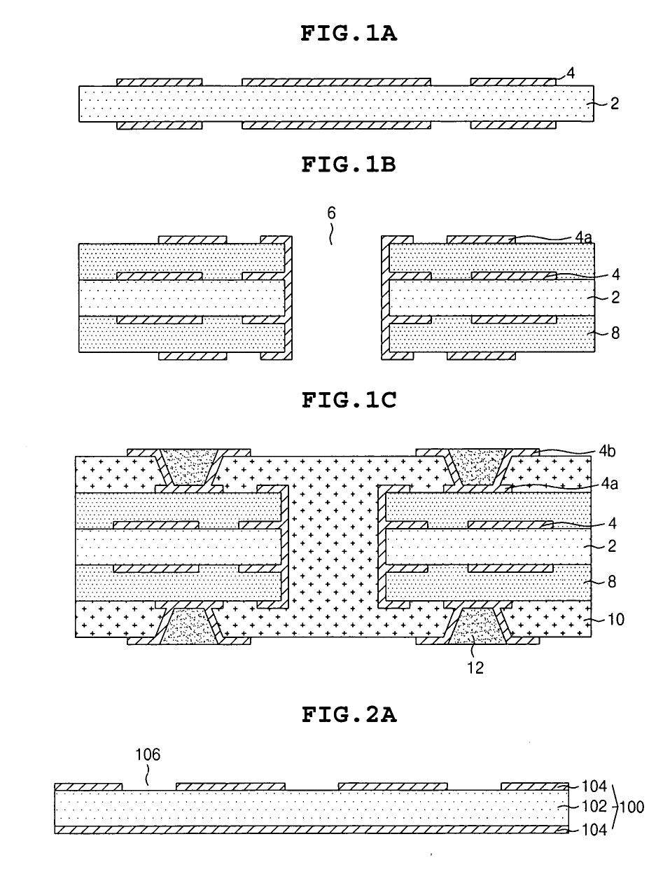

### DESCRIPTION OF THE PREFERRED EMBODIMENTS

Hereinafter, preferred embodiments of the present invention will be described in detail with reference to the attached drawings.

Reference now should be made to the drawings, in which the same reference numerals are used throughout the different drawings to designate the same or similar components.

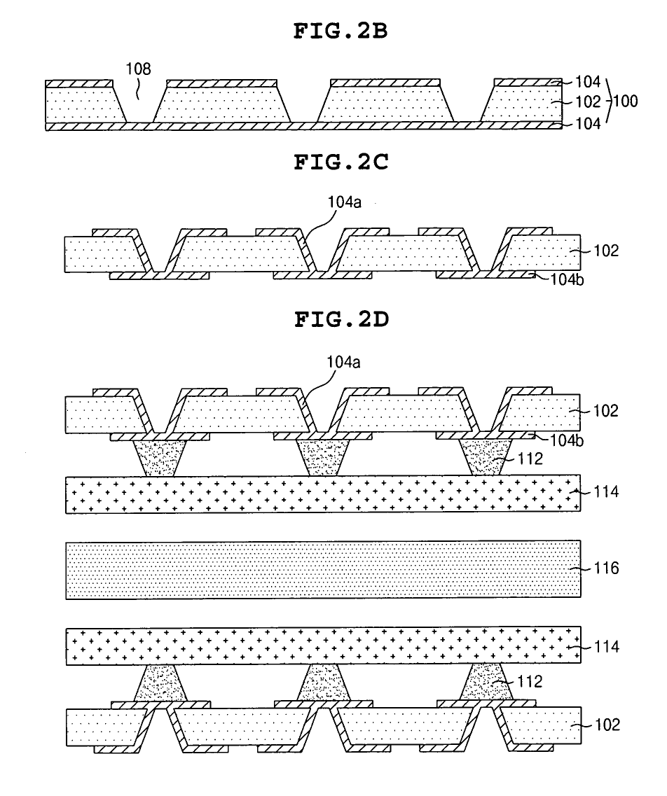

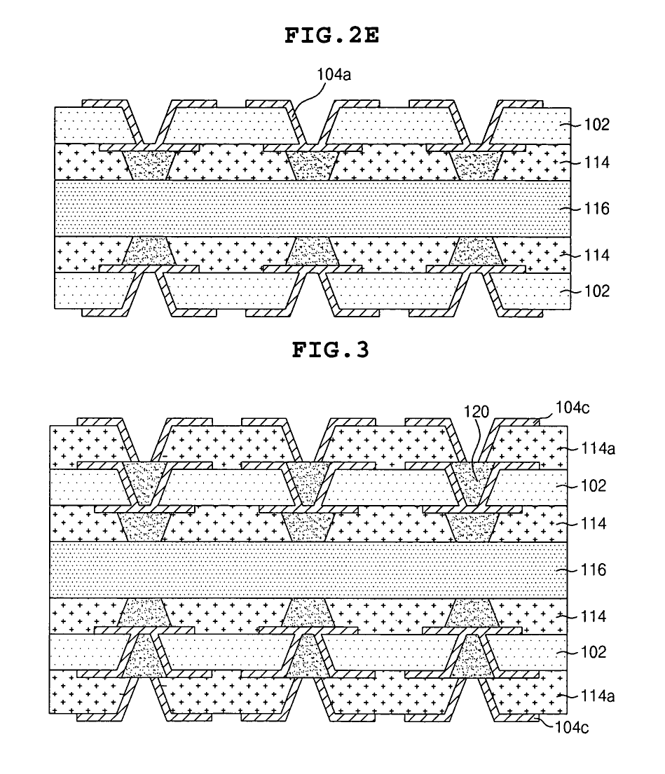

FIGS. 2A to 2E are process views showing a method of manufacturing a multi-layered printed circuit board according to a first embodiment of the present invention.

First, as shown in FIG. 2A, a polyimide copper clad laminate (CCL) 100, in which copper foils are layered on both sides of a first insulation layer 102, is provided, and then windows 106 are formed in the copper foil layered on one side of the first insulation layer 102 such that the first insulation layer 102 is exposed therethrough. Here, the first insulation layer 102 is composed of polyimide.

In this case, each of the windows 101 is formed through photo exposure, development, peeling and etching processes after a dry film (not shown) is applied on the copper foil layered on one side of the first insulation layer 102.

That is, each of the windows 106 is formed by etching the copper foil using a first etchant.

Subsequently, as shown in FIG. 2B, blind via holes 108 are formed by etching the portion of the first insulation layer 102 exposed through the windows 106 using a second etchant such that the copper foil disposed beneath the first insulation layer 102 is exposed.

In this case, the second etchant used for etching the first insulation layer 102 is different from the first etchant used for etching the copper foil. That is, the second etchant, used in FIG. 2B, can etch only the first insulation layer 102 whereas the first etchant, used to form the windows 106 in FIG. 2A, can etch only the copper foil. As a result, a polyimide CCL 100 is prepared.

Here, the blind via holes 108 may be formed using a CO₂ laser.

After the via holes are formed, as shown in FIG. 2C, a copper plated layer is formed on the inner walls of the via holes 108 and the copper foil through an electroless copper plating process and an electrolytic plating process.

In this case, the copper foils layered on both sides of the first insulation layer 102 are electrically connected to each other through the copper plated layer formed on the inner walls of the blind via holes 108.

Here, although an additional copper plated layer formed on the copper foil is not shown in FIG. 2C, a copper plated layer having the same thickness as the copper plated layer formed on the inner walls of the via holes 108 is formed on the copper foil.

Subsequently, a dry film (not shown) is applied on both sides of the first insulation layer 102, and then a circuit pattern 104a, 104b is formed on both sides of the first insulation layer 102 through a photo exposure process and a development process.

After the circuit pattern 104a, 104b is formed, as shown in FIG. 2D, the polyimide CCL 100, in which a circuit pattern 104 is formed, a prepreg 114, an aluminum core layer 116, a prepreg 114, and the polyimide CCL 100, in which a circuit pattern 104a, 104b is formed, are sequentially disposed from bottom to top. Then, bumps 112 are formed between the prepreg 114 and the circuit pattern 104a, 104b formed in the polyimide CCL 100, using electroconductive paste.

Subsequently, the above constituents are integrally layered by heating and pressing them using a vacuum press.

In this case, when a printed circuit board is configured using only the polyimide CCL 100, the printed circuit board is considerably bent so that the shape thereof cannot be normally maintained. Therefore, the aluminum core layer 116 serves to prevent the printed circuit board from being bent.

Consequently, according to the present invention, a multi-layered printed circuit board, in which an aluminum core 116 for radiating heat generated from active devices and passive devices is disposed in the center thereof, and in which a prepreg 114 and a polyimide CCL 100 having a circuit pattern 104a, 104b are sequentially layered on the aluminum core 116, is manufactured.

As described above, in the above embodiment of the present invention, only a method of manufacturing a four-layered printed circuit board in which a circuit layer is configured in the form of a four-layered structure is described, but six or more layered printed circuit boards, as shown in FIG. 3, may be manufactured, depending on the use of the printed circuit board.

When the printed circuit board is configured in the form of a structure having six or more layers, as shown in FIG. 3, the blind via holes, other than the via holes formed in the outermost layers of the printed circuit board, are filled with electroconductive paste 120.

In this case, the blind via holes may be filled through a copper plating process.

As shown in FIG. 3, when the printed circuit board is configured in the form of a structure having six or more layers, each of the outermost layers of the printed circuit board is a prepreg 114a, but may be a polyimide layer.

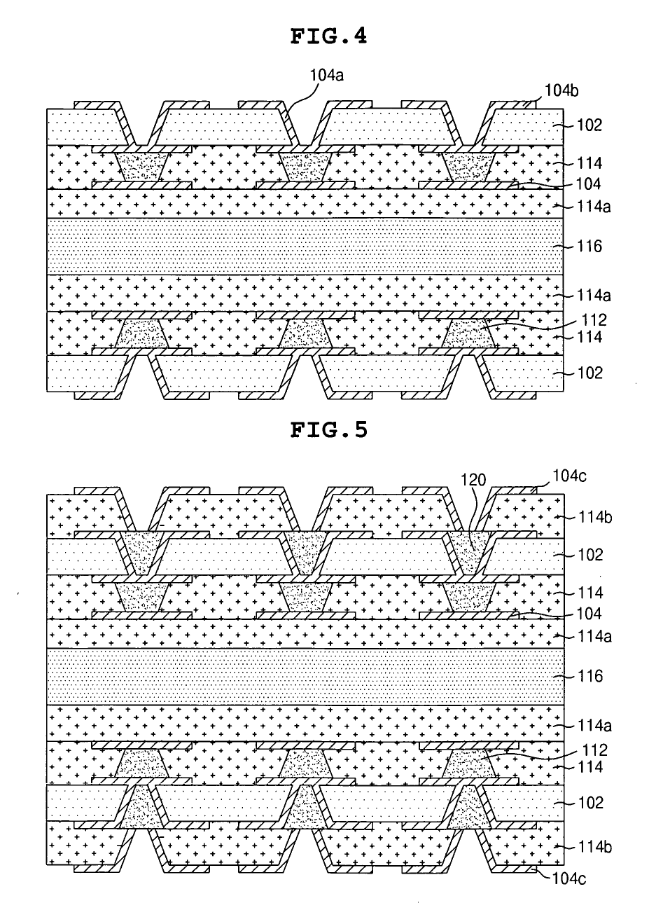

FIG. 4 is a cross-sectional view showing a multi-layered printed circuit board manufactured using the method shown in FIGS. 2A to 2E, according to a third embodiment of the present invention.

Referring to FIG. 4, a first substrate, manufactured in the way shown in FIGS. 2A to 2C, in which a circuit pattern 104a, 104b is formed in a polyimide copper clad laminate (CCL) 100, is provided.

Subsequently, a first prepreg 114a and copper foil are sequentially layered on both sides of an aluminum core layer 116, or one-sided copper clad laminates, in each of which copper foil is layered on one side of the first prepreg 114a, are layered on both sides of the aluminum core layer 116.

After the first prepreg 114a and copper foil are layered on both sides of the aluminum core layer 116, a dry film is applied on the copper foil, and then portion of the dry film applied on the portion of the copper foil, other than the portion of the dry film corresponding to a circuit pattern to be formed later, is removed.

Subsequently, the copper foil exposed by the removal of the dry film is etched using an etchant, thus forming a circuit pattern 104.

After the circuit pattern 104 is formed, the dry film remaining on the copper foil is removed, thus providing a second substrate in which the circuit patterns are formed on the first prepregs 114a layered on both sides of the aluminum core 116.

Thereafter, the first substrate, that is a polyimide CCL 100 in which a circuit pattern 104a, 104b is formed, a second prepreg 114, a second substrate, in which the circuit pattern is formed on the first prepregs 114a layered on both sides of the aluminum core 116, a second prepreg 114 and the other first substrate, that is a polyimide CCL 100 in which a circuit pattern 104a, 104b is formed, are sequentially disposed from bottom to top. Then, bumps 112 are formed between the circuit pattern 104 and the circuit pattern 104a, 104b formed in the polyimide CCL 100, using electroconductive paste.

Subsequently, the above constituents are integrally layered by heating and pressing them using a vacuum press.

Thus, a multi-layered printed circuit board, in which the aluminum core 116 for radiating heat generated from active devices and passive devices is disposed in the center thereof, and in which the second prepreg 114a, in which the circuit pattern 104 is formed, the first prepreg 114, in which the circuit pattern 104 is formed, and a polyimide CCL 100, in which the circuit pattern 104a, 104b is formed, are sequentially layered on the aluminum core 116, is manufactured.

As described above, in this embodiment of the present invention, only a method of manufacturing a six-layered printed circuit board in which a circuit layer is configured in the form of a six-layered structure is described, but eight or more layered printed circuit boards, as shown in FIG. 5, may be manufactured depending on the use of the printed circuit board.

When the printed circuit board is configured in the form of a structure having eight or more layers, as shown in FIG. 5, the blind via holes, other than the via holes formed in the outermost layers of the printed circuit board, are filled with electroconductive paste 120.

In this case, the blind via holes may be filled through a copper plating process.

Further, as shown in FIG. 5, when the printed circuit board is configured in the form of a structure having eight or more layers, each of the outermost layers of the printed circuit board is a prepreg 114b, but may be a polyimide layer.

Here, the printed circuit board is shown and described as being manufactured in such a way that the first substrate, that is the polyimide CCL 100 in which the circuit pattern 104a, 104b is formed, is prepared, and then the second substrate, in which the circuit pattern is formed on the second prepregs 114a layered on both sides of the aluminum core 116, is prepared, for the convenience of description. However, the first substrate and the second substrate may be sequentially or simultaneously prepared.

As described above, according to the method of manufacturing a multi-layered printed circuit board according to the embodiments of the present invention, since an aluminum core layer 116 for radiating heat generated from active devices and passive devices is disposed in the center thereof and a polyimide CCL 100, in which a prepreg 114 and a circuit pattern 104a, 104b are formed on both sides of the aluminum core layer 116, is integrally layered, the cost and time required to produce the multi-layered printed circuit board can be decreased.

Further, according to the method of manufacturing a multi-layered printed circuit board according to the embodiments of the present invention, since the aluminum core layer 116 serves to radiate the heat generated from active devices and passive devices, the heat radiation characteristics and bending strength of the multi-layered printed circuit board can be improved.

Further, according to the method of manufacturing a multi-layered printed circuit board according to the embodiments of the present invention, since a polyimide CCL, which has the circuit and the plating which can be conducted through roll to roll methods, is used, the process of manufacturing a printed circuit board can be designed to be continuous, and thus personnel expenses can be decreased.

Further, according to the method of manufacturing a multi-layered printed circuit board according to the embodiments of the present invention, since blind via holes are formed in a polyimide CCL using an etchant, the cost allocated to laser processing can be reduced.

Finally, according to the method of manufacturing a multi-layered printed circuit board according to the embodiments of the present invention, since a concurrent layering process and a roll to roll process are employed and blind via holes are formed using a chemical etching process, the number of processes is decreased compared to conventional methods of manufacturing a multi-layered printed circuit board using sequential layering methods, and thus the manufacturing time thereof can be reduced.

As described above, according to the present invention, since an aluminum core layer for radiating heat generated from active devices and passive devices is disposed in the center thereof, and a polyimide CCL 100, in which a first prepreg 114 and a circuit pattern 104a, 104b are formed on both sides of the aluminum core layer 116, is integrally layered, the cost and time required to produce the multi-layered printed circuit board can be decreased.

Further, according to the present invention, since the aluminum core layer 116 serves to radiate the heat generated from active devices and passive devices, the heat radiation characteristics and bending strength of the multi-layered printed circuit board can be improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing a multi-layered printed circuit board, comprising:
(a) preparing a polyimide copper clad laminate (CCL), in which copper foils are layered on both sides of a polyimide layer, and then removing portions of the copper foils corresponding to via holes to be formed, to form windows through which the polyimide layer is exposed;
(b) forming the via holes in the polyimide layer such that the copper foil formed beneath the polyimide layer is exposed through the windows;
(c) forming a copper plating layer on an inner wall of the via holes and the copper foil and then forming a circuit pattern; and
(d) sequentially disposing the first polyimide CCL in which the circuit pattern is formed, a first prepreg, an aluminum core layer, a second prepreg, and the second polyimide CCL, in which the circuit pattern is formed, forming bumps between the aluminum core layer and the circuit patterns, and then pressing them using a press while heating them.

2. The method of manufacturing a multi-layered printed circuit board according to claim 1, wherein, in the forming the via holes in (b), the via holes are formed using a CO₂ laser.

3. The method of manufacturing a multi-layered printed circuit board according to claim 1, wherein, in the forming the via holes in (b), the via holes are formed by etching the polyimide layer exposed through the windows, using an etchant.

4. The method of manufacturing a multi-layered printed circuit board according to claim 3, wherein, in the preparing a polyimide copper clad laminate in (a), the windows are formed by etching the copper foil using an etchant that is different from the etchant for etching the polyimide CCL.

5. A method of manufacturing a multi-layered printed circuit board, comprising:
(a) preparing a polyimide copper clad laminate (CCL), in which copper foils are layered on both sides of a polyimide layer, and then removing portions of the copper foils corresponding to via holes to be formed, to form windows through which the polyimide layer is exposed;
(b) forming the via holes in the polyimide layer such that the copper foil, formed beneath the polyimide layer, is exposed through the windows;
(c) forming a copper plating layer on an inner wall of the via holes and the copper foil and then forming a first circuit pattern;
(d) sequentially layering a prepreg and a copper foil on both sides of an aluminum core layer and then forming a second circuit pattern using the copper foil; and
(e) sequentially disposing the first polyimide CCL in which the first circuit pattern is formed, the aluminum core layer in which the second circuit pattern is formed, and the second polyimide CCL in which the first circuit pattern is formed, forming bumps between the first circuit patterns and the second circuit patterns, and then pressing them using a press while heating them.

6. The method of manufacturing a multi-layered printed circuit board according to claim 5, wherein, in the forming the via holes in (b), the via holes are formed using a CO₂ laser.

7. The method of manufacturing a multi-layered printed circuit board according to claim 5, wherein, in the forming the via holes in (b), the via holes are formed by etching the polyimide layer exposed through the windows, using an etchant.

8. The method of manufacturing a multi-layered printed circuit board according to claim 7, wherein, in the preparing a polyimide copper clad laminate in (a), the windows are formed by etching the copper foil using an etchant that is different from the etchant for etching the polyimide CCL.

9. The method of manufacturing a multi-layered printed circuit board according to claim 5, wherein the first and second polyimide CCLs in each of which the first circuit pattern is formed and the aluminum core layer in which the second circuit pattern is formed are formed simultaneously.
